(19) United States
(12) Patent Application Publication
(10) Pub. No.: US 2024/0405040 A1
(43) Pub. Date: Dec. 5, 2024

(54) SEMICONDUCTOR DEVICE

(71) Applicant: SAMSUNG ELECTRONICS CO., LTD., Suwon-si (KR)

(72) Inventors: Seonghoon Ko, Suwon-si (KR); Jae Ho Kim, Suwon-si (KR); Wook Lee, Suwon-si (KR)

(21) Appl. No.: 18/423,984

(22) Filed: Jan. 26, 2024

(30) Foreign Application Priority Data
May 31, 2023 (KR) 10-2023-0070478

(51) Int. Cl. H01L 27/146

(52) U.S. Cl. CPC H01L 27/14614; H01L 27/14636; H01L 27/14621; H01L 27/14627; H01L 27/1463

(57) ABSTRACT

The present disclosure relates to semiconductor device. One example semiconductor device includes a plurality of unit pixels, where each unit pixel of the plurality of unit pixels includes a pair of transfer gates including a first transfer gate and a second transfer gate, a photoelectric converter, and a floating diffusion region spaced apart from the photoelectric converter. The first transfer gate and the second transfer gate are disposed asymmetrically with respect to the photoelectric converter and the floating diffusion region.

### CROSS-REFERENCE TO RELATED APPLICATION

This application claims priority to Korean Patent Application No. 10-2023-0070478 filed in the Korean Intellectual Property Office on May 31, 2023, the disclosure of which is hereby incorporated by reference in its entirety.

### BACKGROUND

An image sensor is a semiconductor device that converts an optical image into an electrical signal. The image sensor may be classified into a charge coupled device (CCD) type and a complementary metal oxide semiconductor (CMOS) type. The CMOS image sensor is abbreviated as CIS (CMOS image sensor). The CIS includes a plurality of pixels two-dimensionally arranged. Each of the pixels includes a photodiode, a floating diffusion region, and a transfer gate. The photodiode serves to convert incident light into an electrical signal. The floating diffusion region serves to temporarily store the electric signal converted by the photodiode. The transfer gate serves to control the electrical connection between the photodiode and the floating diffusion region.

### SUMMARY

The present disclosure relates to enhancing the function of a transfer gate, as well as reducing defects due to the transfer gate.

Various implementations of the present disclosure can exhibit the above-mentioned advantages. Other advantages can be understood from the following description by those having ordinary skill in the art to which the present disclosure pertains.

In some implementations, a semiconductor device includes a plurality of unit pixels, wherein each of the plurality of unit pixels may include a first transfer gate and a second transfer gate making a pair, a photoelectric converter, and a floating diffusion region positioned to be spaced apart from the photoelectric converter, the first transfer gate and the second transfer gate may be disposed asymmetrically with respect to the photoelectric converter and the floating diffusion region.

In some implementations, a semiconductor device includes a first substrate having a first surface and a second surface opposite to the first surface, and including a pixel array region including a plurality of unit pixels and an edge region, an anti-reflection structure disposed on the second surface, a pixel separator disposed on the first substrate to separate the plurality of unit pixels, a color filter disposed on the anti-reflection structure, a micro lens array disposed on the color filter, a first interlayer insulating layer disposed on the first surface of the first substrate, a first wiring layer disposed within the first interlayer insulating layer, a second interlayer insulating layer disposed under the first interlayer insulating layer, a second wiring layer disposed within the second interlayer insulating layer, and a second substrate disposed under the second interlayer insulating layer, wherein each of the plurality of unit pixels include a first transfer gate and a second transfer gate making a pair, a photoelectric converter, and a floating diffusion region positioned to be spaced apart from the photoelectric converter, the first transfer gate and the second transfer gate may be disposed asymmetrically with respect to the photoelectric converter and the floating diffusion region.

In some implementations, a semiconductor device includes a first sub-chip including a first substrate having a first surface and a second surface opposite to the first surface, and including a plurality of unit pixel array regions and an edge region, an anti-reflection structure disposed on the second surface, a pixel separator disposed on the first substrate to separate the plurality of unit pixels, a color filter disposed on the anti-reflection structure, a micro lens array disposed on the color filter, a first interlayer insulating layer disposed on the first surface of the first substrate, and a first wiring layer disposed within the first interlayer insulating layer, a second sub-chip including a second substrate disposed under the first interlayer insulating layer, a second interlayer insulating layer disposed under the second substrate, and a second wiring layer disposed within the second interlayer insulating layer, and a third sub-chip including a third interlayer insulating layer disposed under the second interlayer insulating layer, a third wiring layer disposed within the third interlayer insulating layer, and a third substrate disposed under the third interlayer insulating layer, wherein each of the plurality of unit pixels includes a first transfer gate and a second transfer gate making a pair, a photoelectric converter, and a floating diffusion region positioned to be spaced apart from the photoelectric converter, the first transfer gate and the second transfer gate may be disposed asymmetrically with respect to the photoelectric converter and the floating diffusion region.

In some implementations, by sequentially applying an off voltage to the two transfer gates of a dual transfer gate, a backflow phenomenon in which electrons return to the photoelectric converter from the floating diffusion region can be prevented.

In some implementations, by disposing one of the dual transfer gates separately from the floating diffusion region, point fixed pattern noise can be reduced.

### BRIEF DESCRIPTION OF THE DRAWINGS

FIG. 1 is a block diagram illustrating an example of an image sensor.

FIG. 2 is a circuit diagram of an example of an active pixel sensor array of the image sensor.

FIG. 3 is an example top plan view of the image sensor.

FIG. 4 is an example cross-sectional view taken along A-A′ line of FIG. 3.

FIG. 5 is an example partial top plan view of the image sensor of FIG. 3.

FIG. 6 is an example cross-sectional view taken along B-B′ line of FIG. 5 on which first and second transfer gates are projected.

FIG. 7 is an example cross-sectional view taken along B-B′ line of FIG. 5 on which a dual transfer gate is projected.

FIG. 8 is an example schematic view illustrating prevention of a backflow phenomenon by sequentially applying an off voltage to the two transfer gates of the dual transfer gate in the image sensor.

FIG. 9 is an example partial top plan view of the image sensor.

FIG. 10 is a cross-sectional view of an example of an image sensor.

FIG. 11 is an example partial top plan view of the image sensor of FIG. 10.

### DETAILED DESCRIPTION

The present disclosure will be described in detail hereinafter with reference to the accompanying drawings, in which implementations of the present disclosure are shown. As those skilled in the art would realize, the described implementations may be modified in various different ways, all without departing from the spirit or scope of the present disclosure. The drawings and descriptions are to be regarded as illustrative in nature and not restrictive. Like reference numbers designate like elements throughout the specification. Size and thickness of each constituent element in the drawings are illustrated for better understanding and ease of description, but the following implementations are not limited thereto. In the drawings, the thickness of layers, films, plates, and regions may be exaggerated for clarity. In the drawings, the thickness of some layers and regions may be exaggerated for ease of description. As used herein, the singular forms are intended to include the plural forms unless the context clearly indicates otherwise. As used herein, the term “and/or” includes any combination of the terms “and” and “or” for the meaning and interpretation. For example, “A and/or B” may be understood to mean “A, B, or A and B”. The term “at least one of” in the specification and claims is intended to include “at least one selected from the group of” for purposes of meaning and interpretation. For example, “at least one of A and B” may be understood to mean “A, B, or A and B”. Although terms of “first,” “second,” and the like are used to explain various constituent elements, the constituent elements are not limited to such terms. These terms are only used to distinguish one constituent element from another constituent element. For example, a first constituent element may be referred to as a second constituent element, and similarly, the second constituent element may be referred to as the first constituent element without departing from the range of the present disclosure. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction. For example, spatially relative terms “below,” “lower,” “above,” “upper,” and the like may be used herein for ease of description to describe one element or feature's relationship to another element(s) or feature(s) as illustrated in the drawings.

It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented and the spatially relative descriptors used herein interpreted accordingly.

It should be understood that when an element (or region, layer, part, etc.) is referred to as being “connected to,” “coupled to” another element, it may be directly disposed, connected to, coupled to, or other element intervening elements may be present.

The terms “connected to” or “coupled to” may include a physical or electrical connection or coupling.

Unless otherwise defined, all terms (including technical and scientific terms) used herein have the same meaning as commonly understood by one of ordinary skill in the art to which example implementations belong. It will be further understood that terms, including those defined in generally-used dictionaries, should be interpreted as having a meaning that is consistent with their meaning in the context of the relevant art and will not be interpreted in an idealized or overly formal sense unless expressly so defined herein.

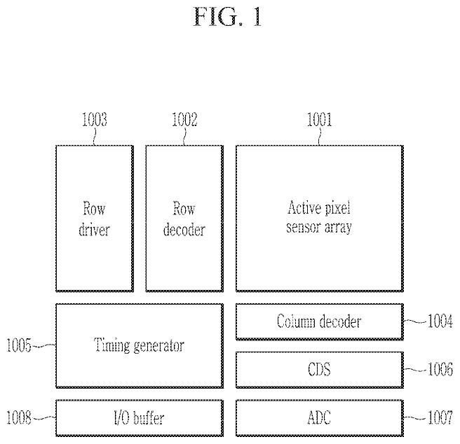

FIG. 1 is a block diagram illustrating an example of an image sensor.

Referring to FIG. 1, an image sensor may include an active pixel sensor array 1001, a row decoder 1002, a row driver 1003, a column decoder 1004, a timing generator 1005, a correlated double sampler (CDS) 1006, an analog to digital converter (ADC) 1007, and an input and output buffer (I/O buffer) 1008.

The active pixel sensor array 1001 may include a plurality of two-dimensionally arranged unit pixels, and may convert an optical signal into an electrical signal. The active pixel sensor array 1001 may be driven by a plurality of driving signals such as a pixel selection signal, a reset signal, and a charge transfer signal from the row driver 1003. In addition, the converted electrical signal may be provided to the CDS 1006.

The row driver 1003 may provide a plurality of driving signals for driving a plurality of unit pixels to the active pixel sensor array 1001 according to a result decoded by the row decoder 1002. When unit pixels are arranged in a matrix format, driving signals may be provided for each row.

The timing generator 1005 may provide a timing signal and a control signal to the row decoder 1002 and the column decoder 1004.

The CDS 1006 may receive, hold, and sample the electrical signal generated by the active pixel sensor array 1001. The CDS 1006 may double sample a specific noise level and a signal level caused by an electrical signal, and output a difference level corresponding to a difference between the noise level and the signal level.

The ADC 1007 may convert an analog signal corresponding to a difference level output from the CDS 1006 into a digital signal and output the converted digital signal.

The I/O buffer 1008 may latch the digital signal, and the latched signal may sequentially output the digital signal to a video signal processor (not shown) according to a decoding result in the column decoder 1004.

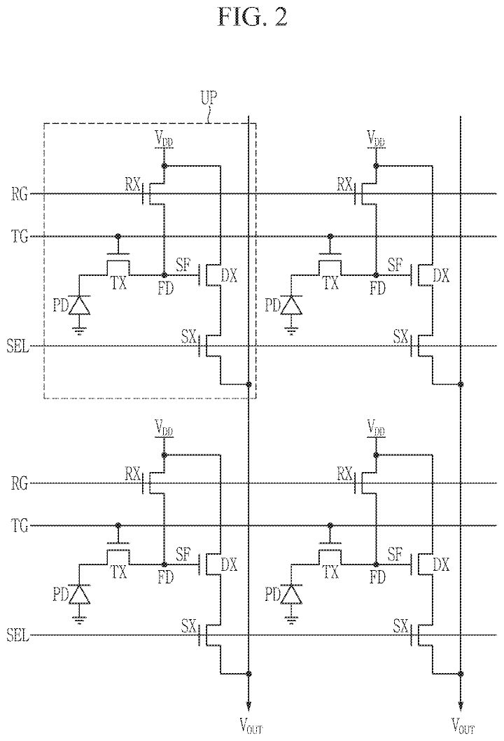

FIG. 2 is a circuit diagram of an example of an active pixel sensor array of the image sensor.

Referring to FIGS. 1 and 2, the sensor array 1001 includes a plurality of unit pixels UP, and the unit pixels UP may be arranged in a matrix format. Each of the unit pixels UP may include a transfer transistor TX. Each of the unit pixels UP may further include logic transistors RX, SX, and DX. The logic transistor may be a reset transistor RX, a selection transistor SX, or a source follower transistor DX. The transfer transistor TX may include a transfer gate TG. The transfer gate TG may be a dual transfer gate in which two transfer gates make a pair. Each of the unit pixels UP may further include a photoelectric converter PD and a floating diffusion region FD. The logic transistors RX, SX, and DX may be shared among the plurality of unit pixels UP.

The photoelectric converter PD may generate and accumulate photocharges in proportion to the amount of light incident from the outside. The photoelectric converter PD may include a photodiode, a phototransistor, a photo gate, a pinned photodiode, and a combination thereof. The transfer transistor TX may transfer charges generated by the photoelectric converter PD to the floating diffusion region FD. The floating diffusion region FD may receive and accumulate charges generated by the photoelectric converter PD. The source follower transistor DX may be controlled according to the amount of photocharges accumulated in the floating diffusion region FD.

The reset transistor RX may periodically reset charges accumulated in the floating diffusion region FD. A drain electrode of the reset transistor RX may be connected to the floating diffusion region FD, and a source electrode of the reset transistor RX may be connected to a power source voltage VDD. When the reset transistor RX is turned on, the power source voltage VDD connected to the source electrode of the reset transistor RX may be applied to the floating diffusion region FD. Therefore, when the reset transistor RX is turned on, the charges accumulated in the floating diffusion region FD are discharged and the floating diffusion region FD may be reset.

The source follower transistor DX including the source follower gate electrode SF may serve as a source follower buffer amplifier. The source follower transistor DX may amplify a potential change in the floating diffusion region FD and output it to an output line Vout.

The selection transistor SX including a selection gate electrode SEL may select unit pixels UP to be read in units of rows. When the selection transistor SX is turned on, the power source voltage VDD may be applied to the drain electrode of the source follower transistor DX.

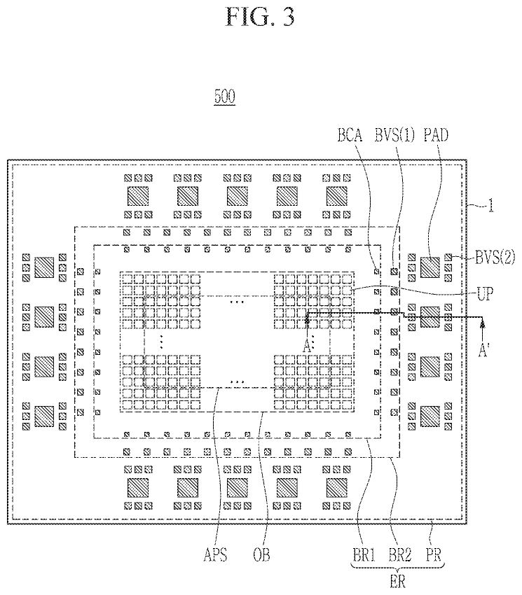

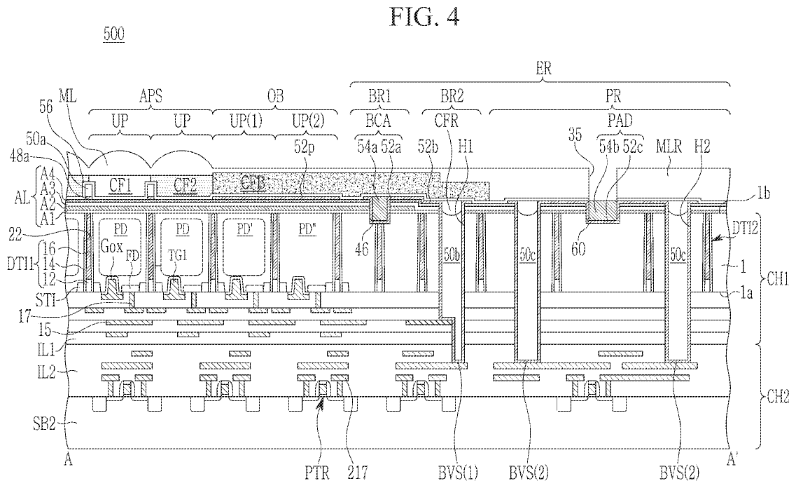

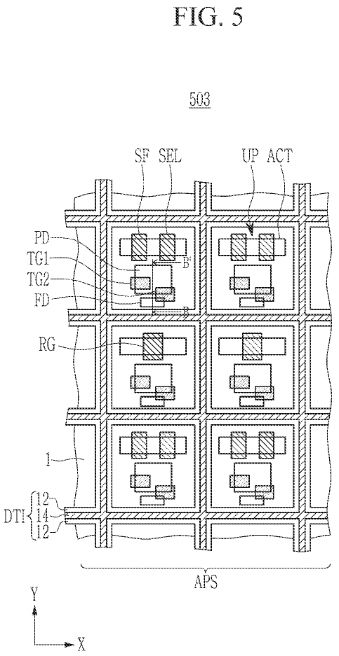

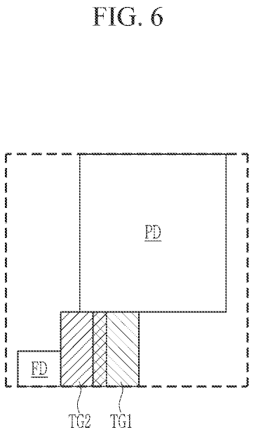

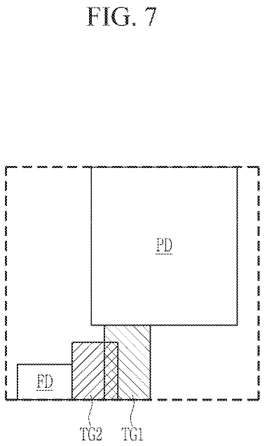

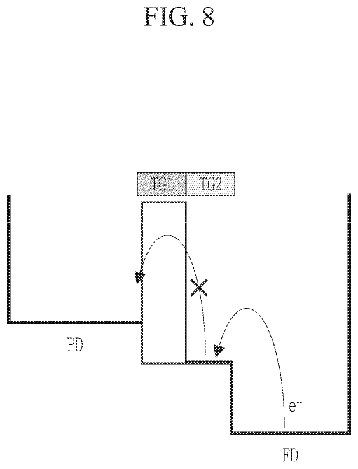

FIG. 3 is an example top plan view of the image sensor. FIG. 4 is an example cross-sectional view taken along A-A′ line of FIG. 3. FIG. 5 is an example partial top plan view of the image sensor of FIG. 3. FIG. 6 is an example cross-sectional view taken along B-B′ line of FIG. 5 on which first and second transfer gates are projected. FIG. 7 is an example cross-sectional view taken along B-B′ line of FIG. 5 on which a dual transfer gate is projected. FIG. 8 is an example schematic view illustrating prevention of a backflow phenomenon by sequentially applying an off voltage to the two transfer gates of the dual transfer gate in the image sensor.

Referring to FIGS. 3 and 4, an image sensor 500 according to an implementation may have a structure in which first and second sub-chips CH1 and CH2 are bonded. The first sub-chip CH1 may be disposed on the second sub-chip CH2. The first sub-chip CH1 includes a first substrate 1. The first substrate 1 may be, for example, a silicon single crystal wafer, a silicon epitaxial layer, or a silicon on insulator (SOI) substrate. The first substrate 1 may be doped with impurities of first conductivity type, for example. For example, the first conductivity type may be a P-type. The first substrate 1 includes a front side 1a and a back side 1b opposite to each other.

In the present specification, the front side 1a may be referred to as a first side 1a, and the back side 1b may also be referred to as a second side 1b. The first substrate 1 may include a pixel array region APS, an optical black region OB, and an edge region ER.

The pixel array region APS and the optical black region OB may each include a plurality of unit pixels UP.

The optical black region OB may surround the pixel array region APS. The edge region ER may surround the pixel array region APS and the optical black region OB. The edge region ER may include a contact region BR1, a via region BR2, and a pad region PR. The via region BR2 may be positioned between the contact region BR1 and the pad region PR.

The pad region PR may be positioned at the outermost part of the edge region ER.

A first pixel separator DTI1 may be disposed in the first substrate 1 in the pixel array region APS and the optical black region OB to separate/limit the unit pixels UP. The first pixel separator DTI1 may extend to the contact region BR1 of the edge region ER. The first pixel separator DTI1 may have a planar mesh shape.

Back side contacts BCA, back side vias BVS, and back side conductive pads PAD may be disposed on the back side 1b of the first substrate 1 in the edge region ER. The back side vias BVS may include first back side vias BVS(1) and second back side vias BVS(2).

The first pixel separator DTI1 and a second pixel separator DTI2 are respectively positioned in a deep trench 22 formed from the front side 1a to the back side 1b of the first substrate 1. The first pixel separator DTI1 and the second pixel separator DTI2 may be frontside deep trench separation (FDTI). The first pixel separator DTI1 and the second pixel separator DTI2 may include a filling insulating pattern 12, a separation insulating pattern 14, and a separation conductive pattern 16, respectively.

The filling insulating pattern 12 may be interposed between the separation conductive pattern 16 and a first interlayer insulating layer IL. The separation insulating pattern 14 may be interposed between the separation conductive pattern 16 and the first substrate 1, and between the filling insulating pattern 12 and the first substrate 1.

The filling insulating pattern 12 and the separation insulating pattern 14 may be formed of an insulating material having a refractive index different from that of the first substrate 1. The filling insulating pattern 12 and the separation insulating pattern 14 may include, for example, silicon oxide. The separation conductive pattern 16 may be spaced apart from the first substrate 1. The separation conductive pattern 16 may include a polysilicon layer or a silicon germanium layer doped with impurities. The impurity doped in the polysilicon or silicon germanium layer may be, for example, one of boron, phosphorus, and arsenic.

Alternatively, the separation conductive pattern 16 may include a metal layer.

The first pixel separator DTI1 and the second pixel separator DTI2 have a narrower horizontal cross-section from the front side 1a toward the back side 1b of the first substrate 1, respectively, as shown in FIG. 4.

The second pixel separator DTI2 may also be referred to as a “substrate separator.”

In the unit pixels UP, the photoelectric converters PDs may be respectively disposed in the first substrate 1. The photoelectric converters PDs may be doped with impurities of a second conductivity type opposite to the first conductivity type. The second conductivity type may be, for example, N-type. N-type impurities doped in the photoelectric converter PD may form a PN junction with P-type impurities doped in the first substrate 1 to provide a photodiode.

Element separators STI (the element separators may be Shallow Trench Insulators) adjacent to the front side 1a may be disposed in the first substrate 1. The element separators STI may be penetrated by the first pixel separator DTI1. The element separators STIs may define active regions ACTs adjacent to the front side 1a in each unit pixel UP. The active regions ACTs may be provided for the transistors TX, RX, DX, and SX of FIG. 2.

Referring to FIGS. 4 and 5, first and second transfer gates TG1 and TG2 forming the dual transfer gate may be disposed on the front side 1a of the first substrate 1 in each unit pixel UP. Portions of the first and second transfer gates TG1 and TG2 may extend into the first substrate 1. The first and second transfer gates TG1 and TG2 may be vertical types. Alternatively, the first and second transfer gates TG1 and TG2 may be planar types that do not extend into the first substrate 1 and have flat shapes. A gate insulating layer Gox may be interposed between the first and second transfer gates TG1 and TG2 and the first substrate 1. The floating diffusion region FD may be disposed in the first substrate 1 at one side of the first and second transfer gates TG1 and TG2. The floating diffusion region FD may be doped with impurities of the second conductivity type, for example.

Referring to FIGS. 5 and 6, the first transfer gate TG1 and the second transfer gate TG2 may be disposed asymmetrically with respect to the photoelectric converter PD and the floating diffusion region FD. For example, the first transfer gate TG1 may be disposed to contact the photoelectric converter PD and spaced apart from the floating diffusion region FD. On the other hand, the second transfer gate TG2 may be disposed to contact both the photoelectric converter PD and the floating diffusion region FD. Alternatively, as shown in FIG. 7, the first transfer gate TG1 may be disposed to contact the photoelectric converter PD and to be spaced apart from the floating diffusion region FD, and the second transfer gate TG2 may be disposed to be spaced apart from the photoelectric converter PD and contact the floating diffusion region FD. The first transfer gate TG1 and the second transfer gate TG2 may be respectively disposed on either side of a cross-section cut vertically along the center of the transfer pass through which electrons are transferred from the photoelectric converter PD to the floating diffusion region FD (the cross-section cut along the B-B′ line, hereinafter referred to as the “electron transfer pass center cross-section”).

The first transfer gate TG1 and the second transfer gate TG2 may be disposed asymmetrically with respect to the electron transfer pass center cross-section.

Referring back to FIG. 5, in a plan view, the first transfer gate TG1 may overlap the photoelectric converter PD and may not overlap the floating diffusion region FD. In a plan view, the second transfer gate TG2 may overlap both the photoelectric converter PD and the floating diffusion region FD. Alternatively, in a plan view, the second transfer gate TG2 may overlap the photoelectric converter PD and contact a side surface of the floating diffusion region FD.

Referring to FIGS. 6 and 7, when the first transfer gate TG1 and the second transfer gate TG2 are projected onto the electron transfer pass center cross-section (B-B′ cross-section), the first transfer gate TG1 and the second transfer gate TG2 may partially overlap each other. The first transfer gate TG1 may be in upward and downward contact with the photoelectric converter PD. The second transfer gate TG2 may be in left and right contact with the floating diffusion region FD. The second transfer gate TG2 may also be in upward and downward contact with the photoelectric converter PD.

An on-off voltage may be separately applied to each of the first transfer gate TG1 and the second transfer gate TG2.

Like this, by placing the first transfer gate TG1 and the second transfer gate TG2 asymmetrically with respect to the photoelectric converter PD and the floating diffusion region FD, and applying on-off voltages to the first transfer gate TG1 and the second transfer gate TG2 separately, it is possible to prevent a backflow phenomenon in which electrons return to the photoelectric converter PD from the floating diffusion region FD. This will be described with reference to FIG. 8.

Referring to FIG. 8, the floating diffusion region FD has a lower energy level than the photoelectric converter PD. Therefore, when an on-voltage is applied to the first transfer gate TG1 and the second transfer gate TG2 to lower the energy barrier, electrons flow from the photoelectric converter PD to the floating diffusion region FD and are accumulated therein.

Thereafter, when an off-voltage is applied to the first transfer gate TG1 in contact with the photoelectric converter PD in a state where the on-voltage is applied to the second transfer gate TG2, an energy barrier is formed at the position in contact with the photoelectric converter PD.

Therefore, even if the energy level of the electron transfer path increases by applying the off-voltage to the second transfer gate TG2 thereafter, electrons on the electron transfer path may be prevented from returning to the photoelectric converter PD.

In addition, since the first transfer gate TG1 is spaced apart from the floating diffusion region FD, point fixed pattern noise may be reduced.

The image sensor 500 may be a back light receiving image sensor. Light may be incident into the first substrate 1 through the back side 1b of the first substrate 1. Electron-hole pairs may be generated in the PN junction by the incident light. Electrons thus generated may move to the photoelectric converter PD.

When a voltage is applied to the first and second transfer gates TG1 and TG2, the electrons may move to the floating diffusion region FD.

As shown in FIG. 5, in one of the unit pixels UP, a reset gate RG may be disposed on the front side 1a in contact with the first and second transfer gates TG1 and TG2.

In another one of the unit pixels UP, the source follower gate SF and the selection gate SEL may be disposed on the front side 1a adjacent to the first and second transfer gates TG1 and TG2. The gates TG1, TG2, RG, SF, and SEL may respectively correspond to gates of the transistors TX, RX, DX, and SX of FIG. 2. The gates TG1, TG2, RG, SF, and SEL may overlap the active regions ACTs. In the present exemplary implementations, the reset transistor RX, the selection transistor SX, and the source follower transistor DX may be shared between two adjacent unit pixels UP.

A first unit pixel UP(1) and a second unit pixel UP(2) may be disposed in the optical black region OB of the first substrate 1. In the first unit pixel UP(1), a black photoelectric converter PD′ is provided in the first substrate 1. In the second unit pixel UP(2), a dummy region PD″ may be provided in the first substrate 1. The black photoelectric converter PD′ may be doped with, for example, impurities of the second conductivity type different from the first conductivity type. The second conductivity type may be, for example, N-type. The pixel array region APS may include a plurality of unit pixels UP. The black photoelectric converter PD′ has a structure similar to that of the photoelectric converter PD, but may not perform the same operation as the photoelectric converter PD (i.e., an operation of receiving light and generating an electrical signal). The dummy region PD″ may not be doped with impurities. A signal generated in the dummy region PD″ may be used as data for removing process noise thereafter.

The first sub-chip CH1 may further include first interlayer insulating layers IL disposed on the front side 1a. The first interlayer insulating layers IL may be made of a multilayer of at least one layer selected from a silicon oxide layer, a silicon nitride layer, a silicon oxynitride layer, and a porous low-k dielectric layer. First wires 15 may be disposed between or inside the first interlayer insulating layers IL. The floating diffusion region FD may be connected to the first wires 15 by a first contact plug 17. The first contact plug 17 may pass through the first interlayer insulating layer IL (lowest layer) closest to the front side 1a among the first interlayer insulating layers IL in the pixel array region APS.

The second sub-chip CH2 may include a second substrate SB2, peripheral transistors PTRs disposed thereon, and second interlayer insulating layers IL2 covering them.

Second wires 217 may be disposed in the second interlayer insulating layers IL2. The second sub-chip CH2 may include circuits for storing electrical signals generated by the first sub-chip CH1.

Referring to FIG. 4, an anti-reflection structure AL may be disposed on the back side 1b of the first substrate 1. The anti-reflection structure AL may include a first insulating layer A1, a conductive layer A2, a second insulating layer A3, and a third insulating layer A4 sequentially stacked. The first insulating layer A1, the second insulating layer A3, and the third insulating layer A4 may each include different materials. In an implementation, the first insulating layer A1 may include aluminum oxide, the second insulating layer A3 may include silicon oxide, and the third insulating layer A4 may include hafnium oxide. The conductive layer A2 is an electrically conductive layer and may include titanium oxide.

In the present specification, the first insulating layer A1 may be referred to as a “first anti-reflection coating,” the conductive layer A2 may be referred to as a “second anti-reflection coating,” the second insulating layer A3 may be referred to as a “third anti-reflection coating,” and the third insulating layer A4 may be referred to as a “fourth anti-reflection coating.”

The first substrate 1 may have a first refractive index n1, the first insulating layer A1 may have a second refractive index n2, the conductive layer A2 may have a third refractive index n3, and the second insulating layer A3 may have a fourth refractive index n4. An average value {(n2+n3)/2} of the second refractive index n2 and the third refractive index n3 may be smaller than the first refractive index n1 and larger than the fourth refractive index n4. The first refractive index n1 may be 4.0 to 4.4. The second refractive index n2 may be 2.0 to 3.0. The third refractive index n3 may be 2.2 to 2.8. The fourth refractive index n4 may be 1.0 to 1.9.

The first insulating layer A1 may have a first thickness T1, the conductive layer A2 may have a second thickness T2, the second insulating layer A3 may have a third thickness T3, and the third insulating layer A4 may have a fourth thickness T4. In this case, the second thickness T2 may be larger than each of the first thickness T1 and the fourth thickness T4 and smaller than the third thickness T3.

The first thickness T1 may be 10 Å to 100 Å. The second thickness T2 may be 100 Å to 600 Å. The third thickness T3 may be 600 Å to 900 Å. The fourth thickness T4 may be 20 Å to 200 Å.

By the relationship between the refractive indexes and/or the relationship between the thicknesses, a light L1 incident to a micro lens ML may be refracted and passed through multi-layer structure of the anti-reflection structure AL, and be well incident on the photoelectric converter PD.

Accordingly, it is possible to provide the image sensor 500 having clear image quality by increasing the light reception rate.

In the image sensor 500 according to an implementation, the anti-reflection structure AL may include the conductive layer A2 made of titanium oxide (TiO2), which may entirely reduce the reflectivity of all colors of light, and may further reduce the reflectivity of blue light in particular.

With this, the quantum efficiency (QE) of the blue pixels may be increased.

The first insulating layer A1 may also serve as a negative fixed charge layer. With this, the dark current and the white spot may be improved.

In addition, a predetermined negative potential (voltage) may be applied to the conductive layer A2 so that holes h+ are accumulated near the back side 1b of the first substrate 1.

Accordingly, the effect of improving the dark current and the white spot may be further increased.

Referring to FIGS. 3 and 4, the back side contacts BCA may be disposed on the back side 1b of the first substrate 1 in the contact region BR1. The first back side vias BVS(1) may be disposed on the back side 1b of the first substrate 1 in the via region BR2. The back side conductive pads PAD and the second back side vias BVS(2) may be disposed on the back side 1b of the first substrate 1 in the pad region PR. The second back side vias BVS(2) may be grouped in a predetermined number and disposed around the back side conductive pads PAD, respectively.

Referring to FIG. 4, the back side contacts BCAs may pass through at least a portion of the anti-reflection structure AL and the first substrate 1. The back side contacts BCAs may be disposed in a first back side trench 46. The back side contacts BCAs may include a first conductive pattern 52a and a first metal pattern 54a. The first conductive pattern 52a may conformally cover the side surface and the bottom surface of the first back side trench 46, and may contact and electrically connect to the conductive layer A2 of the anti-reflection structure AL. The first conductive pattern 52a may have a single layer structure or multilayer structure of at least one of a titanium layer, a titanium nitride layer, and a tungsten layer. The first metal pattern 54a may include aluminum, for example. The first metal pattern 54a may fill the first back side trench 46.

The back side contacts BCAs may contact the separation conductive pattern 16 of the first pixel separator DTI1. The back side contacts BCAs may be connected to the first back side vias BVS(1) through a back side connection wire 52b to receive a predetermined negative potential, which can be applied to the separation conductive pattern 16 of the first pixel separator DTI1.

The separation conductive pattern 16 may serve as a common bias line. Accordingly, it is possible to capture holes that may exist on the surface of the first substrate 1 in contact with the first pixel separator DTI1, thereby increasing the dark current improvement effect.

The first back side vias BVS(1) are respectively disposed in first holes H1. The first back side vias BVS(1) may partially penetrate the anti-reflection structure AL, the first substrate 1, the first interlayer insulating layer IL1, and the second interlayer insulating layer IL2. The first back side vias BVS(1) may connect some of the first wires 15 of the first sub-chip CH1 and some of the second wires 217 of the second sub-chip CH2. The first back side vias BVS(1) may conformally fill inner walls and bottom surfaces of the first holes H1. The first back side vias BVS(1) may include the same material as the first conductive pattern 52a and may have the same thickness. The first back side vias BVS(1) may have a single layer structure or a multilayer structure of at least one of a titanium layer, a titanium nitride layer, and a tungsten layer.

One of the first back side vias BVS(1) may be electrically connected to one of the back side contacts BCA by one of the back side connection wires 52b. The back side connection wire 52b may include the same material as the first conductive pattern 52a and may have the same thickness. The back side connection wire 52b may have a single layer structure or a multilayer structure of at least one of a titanium layer, a titanium nitride layer, and a tungsten layer.

The back side conductive pad PAD may be disposed in a second back side trench 60. The back side conductive pad PAD may include a second conductive pattern 52c and a second metal pattern 54b. The second conductive pattern 52c may conformally cover the side surface and the bottom surface of the second back side trench 60. The second conductive pattern 52c may include the same material as the first conductive pattern 52a and may have the same thickness. The second conductive pattern 52c may have a single layer structure or a multilayer structure of at least one of a titanium layer, a titanium nitride layer, and a tungsten layer. The second metal pattern 54b may include aluminum, for example. The second metal pattern 54b may fill the second back side trench 60.

The second back side vias BVS(2) are respectively disposed in the second holes H2. The second back side vias BVS(2) partially penetrate the first insulating layer A1, the first substrate 1, the first interlayer insulating layer IL1, and the second interlayer insulating layer IL2 of the anti-reflection structure AL. The second back side vias BVS(2) may be connected to some of the second wires 217. Although not shown, the second back side vias BVS(2) may be connected to some of the first wires 15. The second back side vias BVS(2) may conformally fill inner walls and bottom surfaces of the second holes H2. The second back side vias BVS(2) may include the same material as the first conductive pattern 52a and may have the same thickness. The second back side vias BVS(2) may have a single layer structure or a multilayer structure of at least one of a titanium layer, a titanium nitride layer, and a tungsten layer. One of the second back side vias BVS(2) may be electrically connected to one of the back side conductive pads PADs by one of the back side connection wires 52b.

A first optical black pattern 52p may be disposed on the anti-reflection structure AL at the edge region ER. The first optical black pattern 52p may include the same material as the first conductive pattern 52a and may have the same thickness. The first optical black pattern 52p may have a single layer structure or a multilayer structure of at least one of a titanium layer, a titanium nitride layer, and a tungsten layer.

Light blocking grid patterns 48a may be disposed on the anti-reflection structure AL in the pixel array region APS. Low refractive index grid patterns 50a may be respectively disposed on the light blocking grid patterns 48a. The light blocking grid pattern 48a and the low refractive index grid pattern 50a overlap the first pixel separator DTI1 and may have a planar grid shape. The light blocking grid pattern 48a may include, for example, at least one of titanium and titanium nitride. All of the low refractive index grid patterns 50a may have the same thickness and include the same organic material. The low refractive index grid pattern 50a may have a lower refractive index than color filters CF1 and CF2. For example, the low refractive index grid pattern 50a may have a refractive index of about less than or equal to 1.3. The light blocking grid pattern 48a and the low refractive index grid pattern 50a may prevent crosstalk between adjacent unit pixels UP.

The color filters CF1 and CF2 may be disposed between the low refractive index grid patterns 50a in the pixel array region APS. The color filters CF1 and CF2 may respectively have one color among blue, green, and red. As another example, the color filters CF1 and CF2 may include other colors such as cyan, magenta, or yellow. In the image sensor according to the present implementation, the color filters CF1 and CF2 may be arranged in a bayer pattern. In another example, the color filters CF1 and CF2 may be arranged in a 2×2 tetra pattern, a 3×3 nona pattern, or a 4×4 hexadeca pattern.

Capping patterns CFRs may be respectively disposed on a first low refractive index protective pattern 50b filling the inside of the first back side vias BVS(1) and on a second low refractive index protective pattern 50c filling the inside of the second back side vias BVS(2). The capping pattern CFR may include, for example, a photoresist material.

A passivation layer 56 may be conformally disposed on the low refractive index grid pattern 50a, the first conductive pattern 52a, the first metal pattern 54a, the second conductive pattern 52c, the back side connection wire 52b, the first optical black pattern 52p, the capping pattern CFR, and a low refractive index residual pattern 50r.

A second optical black pattern CFB may be disposed on the passivation layer 56. The second optical black pattern CFB may include, for example, the same material as a blue color filter.

Micro lenses ML may be disposed on the color filters CF1 and CF2 in the pixel array region APS. Edges of the micro lenses ML may be connected by contacting each other. The micro lenses ML may configure an array.

The micro lenses ML may also be referred to as a “micro lens array.”

A lens residual layer MLR may be disposed on the second optical black pattern CFB at the edge region ER. The lens residual layer MLR may include the same material as the micro lenses ML. An opening 35 exposing the back side conductive pad PAD may be provided in the lens residual layer MLR and the passivation layer 56 in the pad region PR.

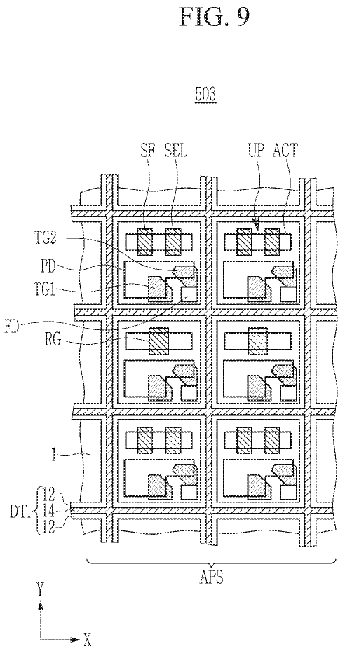

FIG. 9 is an example partial top plan view of the image sensor.

The arrangement of the first and second transfer gates TG1 and TG2, the photoelectric converter PD, and the floating diffusion region FD in each unit pixel UP may be modified in various ways. As shown in FIG. 9, the floating diffusion region FD is disposed at the corner of the unit pixel UP, the photoelectric converter PD is spaced apart from the floating diffusion region FD by a predetermined distance in a plan view, and a first and second transfer gates TG1 and TG2 may be disposed therebetween.

In this case, the first transfer gate TG1 may partially overlap the photoelectric converter PD in a plan view and be spaced apart from the floating diffusion region FD. The second transfer gate TG2 may partially overlap the converter PD and contact the floating diffusion region FD. The vertical disposition of the first and second transfer gates TG1 and TG2, the photoelectric converter PD, and the floating diffusion region FD may have the structure of FIG. 6 or FIG. 7.

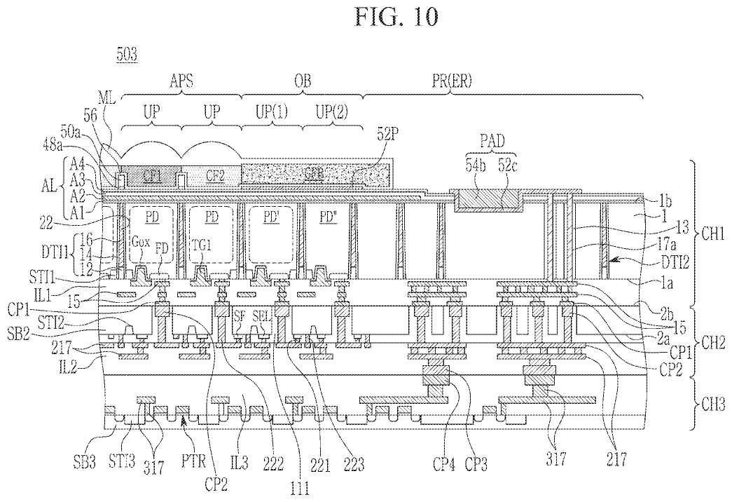

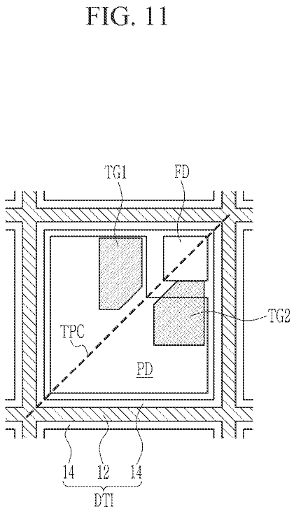

FIG. 10 is a cross-sectional view of an example of an image sensor. FIG. 11 is an example partial top plan view of the image sensor of FIG. 10.

An image sensor 503 according to the implementations of FIGS. 10 and 11 may have a structure in which first to third sub-chips CH1 to CH3 are sequentially bonded.

The first sub-chip CH1 may preferably perform an image sensing function. The first sub-chip CH1 may include the first substrate 1. The first substrate 1 may be, for example, a silicon single crystal wafer, a silicon epitaxial layer, or a silicon on insulator (SOI) substrate. The first substrate 1 may be doped with impurities of the first conductivity type, for example. For example, the first conductivity type may be a P-type. The first substrate 1 includes the front side 1a and the back side 1b opposite to each other. In the present specification, the front side 1a may be referred to as the first side 1a, and the back side 1b may also be referred to as the second side 1b. The first substrate 1 may include the pixel array region APS, the optical black region OB, and the edge region ER.

The pixel array region APS and the optical black region OB may each include the plurality of unit pixels UP. The optical black region OB may surround the pixel array region APS. The edge region ER may surround the pixel array region APS and the optical black region OB. The edge region ER may include the pad region PR. The pad region PR may be positioned at the outermost part of the edge region ER.

The first pixel separator DTI1 may be disposed in the first substrate 1 in the pixel array region APS and the optical black region OB to separate/limit the unit pixels UP. The first pixel separator DTI1 may extend to the contact region BR1 of the edge region ER. The first pixel separator DTI1 may have a planar mesh shape. The second pixel separator DTI2 may be disposed in the first substrate 1 at the edge region ER.

The first pixel separator DTI1 and the second pixel separator DTI2 are respectively positioned in the deep trench 22 formed from the front side 1a to the back side 1b of the first substrate 1. The first pixel separator DTI1 and the second pixel separator DTI2 may be frontside deep trench separation (FDTI). The first pixel separator DTI1 and the second pixel separator DTI2 may include the filling insulating pattern 12, the separation insulating pattern 14, and the separation conductive pattern 16, respectively. The filling insulating pattern 12 may be interposed between the separation conductive pattern 16 and the first interlayer insulating layer IL. The separation insulating pattern 14 may be interposed between the separation conductive pattern 16 and the first substrate 1, and between the filling insulating pattern 12 and the first substrate 1.

The filling insulating pattern 12 and the separation insulating pattern 14 may be formed of an insulating material having a refractive index different from that of the first substrate 1. The filling insulating pattern 12 and the separation insulating pattern 14 may include, for example, silicon oxide. The separation conductive pattern 16 may be spaced apart from the first substrate 1. The separation conductive pattern 16 may include a polysilicon layer or a silicon germanium layer doped with impurities. The impurity doped in the polysilicon or silicon germanium layer may be, for example, one of boron, phosphorus, and arsenic. Alternatively, the separation conductive pattern 16 may include a metal layer.

The first pixel separator DTI1 and the second pixel separator DTI2 may have a narrower horizontal cross-section from the front side 1a toward the back side 1b of the first substrate 1, respectively. The second pixel separator DTI2 may also be referred to as a “substrate separator.”

In the unit pixels UP, the photoelectric converters PD may be respectively disposed in the first substrate 1. The photoelectric converters PD may be doped with impurities of the second conductivity type opposite to the first conductivity type. The second conductivity type may be, for example, N-type. N-type impurities doped in the photoelectric converter PD may form a PN junction with P-type impurities doped in the first substrate 1 to provide a photodiode.

First element separators STI1 adjacent to the front side 1a may be disposed in the first substrate 1. The first element separators STI1 may be penetrated by the first pixel separator DTI1. The first element separators STI1 may define active regions adjacent to the front side 1a in each unit pixel UP. Active regions may be provided for the transistors TX, RX, DX, and SX of FIG. 2.

Referring to FIG. 10, the first and second transfer gates TG1 and TG2 forming the dual transfer gate may be disposed on the front side 1a of the first substrate 1 in each unit pixel UP. Portions of the first and second transfer gates TG1 and TG2 may extend into the first substrate 1. The first and second transfer gates TG1 and TG2 may be vertical types. Alternatively, the first and second transfer gates TG1 and TG2 may be planar types that do not extend into the first substrate 1 and have flat shapes. The gate insulating layer Gox may be interposed between the first and second transfer gates TG1 and TG2 and the first substrate 1. The floating diffusion region FD may be disposed in the first substrate 1 at one side of the first and second transfer gates TG1 and TG2. The floating diffusion region FD may be doped with impurities of the second conductivity type, for example.

Referring to FIG. 11, within each unit pixel UP disposed on the first sub-chip CH1, the first and second transfer gates TG1 and TG2, the photoelectric converter PD, and the floating diffusion region FD may only be placed.

Unlike the implementation of FIG. 5, the selection gates SEL, the source follower gates SF, and reset gate RG may be disposed on the second sub-chip CH2, not disposed on the first sub-chip CH1.

Referring to FIG. 11, the first transfer gate TG1 and the second transfer gate TG2 may be disposed asymmetrically with respect to the photoelectric converter PD and the floating diffusion region FD. The vertical disposition of the first and second transfer gates TG1 and TG2, the photoelectric converter PD, and the floating diffusion region FD may have the structure of FIG. 6 or FIG. 7. For example, the first transfer gate TG1 may be disposed to contact the photoelectric converter PD and spaced apart from the floating diffusion region FD. On the other hand, the second transfer gate TG2 may be disposed to contact both the photoelectric converter PD and the floating diffusion region FD. The first transfer gate TG1 may be disposed to contact the photoelectric converter PD and to be spaced apart from the floating diffusion region FD, and the second transfer gate TG2 may be disposed to be spaced apart from the photoelectric converter PD and contact the floating diffusion region FD. In a plan view, the first transfer gate TG1 may be positioned within a range of the photoelectric converter PD and spaced apart from the floating diffusion region FD. In a plan view, the second transfer gate TG2 may partially overlap the converter PD and contact the floating diffusion region FD.

In FIG. 11, the first transfer gate TG1 and the second transfer gate TG2 may be respectively disposed on both sides of an electron transfer pass center cross-section (a cross-section cut along the TPC line). The first transfer gate TG1 and the second transfer gate TG2 may be disposed asymmetrically with respect to the electron transfer pass center cross-section.

Referring to FIGS. 6 and 7, when the first transfer gate TG1 and the second transfer gate TG2 are projected onto an electron transfer pass center cross-section TPC, the first transfer gate TG1 and the second transfer gate TG2 may partially overlap each other. The first transfer gate TG1 may be in upward and downward contact with the photoelectric converter PD. The second transfer gate TG2 may be in left and right contact with the floating diffusion region FD. The second transfer gate TG2 may be in upward and downward contact with the photoelectric converter PD.

An on-off voltage may be separately applied to each of the first transfer gate TG1 and the second transfer gate TG2.

Like this, by placing the first transfer gate TG1 and the second transfer gate TG2 asymmetrically with respect to the photoelectric converter PD and the floating diffusion region FD, and applying on-off voltages to the first transfer gate TG1 and the second transfer gate TG2 separately, it is possible to prevent a backflow phenomenon in which electrons return to the photoelectric converter PD from the floating diffusion region FD. In addition, since the first transfer gate TG1 is spaced apart from the floating diffusion region FD, point fixed pattern noise may be reduced.

The image sensor 503 may be a back light receiving image sensor. Light may be incident into the first substrate 1 through the back side 1b of the first substrate 1. Electron-hole pairs may be generated in the PN junction by the incident light. Electrons thus generated may move to the photoelectric converter PD. When a voltage is applied to the transfer gate TG, electrons may move to the floating diffusion region FD.

The first sub-chip CH1 may include first and second transfer gates TG1 and TG2 and the first interlayer insulating layers IL1 covering the first and second transfer gates TG1 and TG2 on the front side 1a of the first substrate 1. The first element separator STI1 may be disposed on the first substrate 1 to define active regions. The first sub-chip CH1 may further include internal connection contacts 17a. At least one of the internal connection contacts 17a passes through the filling insulating pattern 12 of the first pixel separator DTI1 in the edge region ER to connect a part of the first wires 15 to the separation conductive pattern 16 of the first pixel separator DTI1, and may apply a negative bias voltage to the separation conductive pattern 16.

At least another one of the internal connection contacts 17a may pass through the filling insulating pattern 12 of the second pixel separator DTI2 under the back side conductive pad PAD, and connect some of the first wires 15 to the separation conductive pattern 16 of the second pixel separator DTI2. A first conductive pad CP1 may be disposed in the first interlayer insulating layer IL1 of the lowermost layer. The first conductive pad CP1 may include copper.

The second sub-chip CH2 may include the second substrate SB2, the selection gates SEL disposed on a front side 2a of the second substrate SB2, the source follower gates SF, reset gates (not shown), and the second interlayer insulating layers IL2 covering them.

A second element separator STI2 may be disposed on the second substrate SB2 to define active regions, and an additional floating diffusion region (not shown) may be disposed in the active region. A plurality of through-holes may be disposed in the second substrate SB2, and through-vias 222 may be disposed in each through-hole. A second conductive pad CP2 may be disposed on the through-via 222 and exposed through the back side 2b side of the second substrate SB2. The second conductive pad CP2 may contact the first conductive pad CP1 of the first sub-chip CH1. A through-hole insulating layer 111 may be filled around the through-via 222 and the second conductive pad CP2. The through-hole insulating layer 111 may be conformally disposed on the front side 2a of the second substrate SB2. Within the through-hole insulating layer 111 and the second interlayer insulating layer IL2, second wires 217 including a via 221 connected to the source follower gate SF and a via 223 connected to the active region of the second substrate SB2, and a third conductive pad CP3 may be disposed.

The source follower gates SF may be connected to the floating diffusion regions FD of the first sub-chip CH1 through the through-via 222 and the second conductive pad CP2, respectively.

Referring to FIG. 10, the through-via 222 may be disposed in a through-hole passing through the second substrate SB2, and the second conductive pad CP2 may be disposed on the through-via 222.

The through-hole insulating layer 111 may be filled around the through-via 222 and the second conductive pad CP2 to insulate between the second substrate SB2 and the through-via 222 and the second conductive pad CP2.

A lower end of the through-via 222 may be connected to the second wires 217. The width of the cross-section of the through-via 222 may increase as the distance from the second conductive pad CP2 increases, and the width of the cross-section of the second conductive pad CP2 may increase as the distance from the through-via 222 increases. The second conductive pad CP2 and the second wires 217 may include copper, and the through-via 222 may include tungsten.

Referring to FIG. 10, the third sub-chip CH3 may include a third substrate SB3, peripheral transistors PTR disposed thereon, and third interlayer insulating layers IL3 covering them. A third element separator STI3 may be disposed on the third substrate SB3 to define active regions. Third wires 317 and fourth conductive pads CP3 may be disposed in the third interlayer insulating layers IL3. The uppermost layer of the third interlayer insulating layer IL3 is in contact with the uppermost layer of the second interlayer insulating layer IL2. The third sub-chip CH3 may include circuits for driving the first and/or second sub-chips CH1 and CH2 or storing electrical signals generated by the first and/or second sub-chips CH1 and CH2.

Referring to FIG. 10, the anti-reflection structure AL may be disposed on the back side 1b of the first substrate 1. The anti-reflection structure AL may include the first insulating layer A1, the conductive layer A2, the second insulating layer A3, and the third insulating layer A4 sequentially stacked. The first insulating layer A1, the second insulating layer A3, and the third insulating layer A4 may each include different materials. In an implementation, the first insulating layer A1 may include aluminum oxide, the second insulating layer A3 may include silicon oxide, and the third insulating layer A4 may include hafnium oxide. The conductive layer A2 is an electrically conductive layer and may include titanium oxide.

In the present specification, the first insulating layer A1 may be referred to as a “first anti-reflection coating,” the conductive layer A2 may be referred to as a “second anti-reflection coating,” the second insulating layer A3 may be referred to as a “third anti-reflection coating,” and the third insulating layer A4 may be referred to as a “fourth anti-reflection coating.”

The first substrate 1 may have a first refractive index n1, the first insulating layer A1 may have a second refractive index n2, the conductive layer A2 may have a third refractive index n3, and the second insulating layer A3 may have a fourth refractive index n4. An average value {(n2+n3)/2} of the second refractive index n2 and the third refractive index n3 may be smaller than the first refractive index n1 and larger than the fourth refractive index n4. The first refractive index n1 may be 4.0 to 4.4. The second refractive index n2 may be 2.0 to 3.0. The third refractive index n3 may be 2.2 to 2.8. The fourth refractive index n4 may be 1.0 to 1.9.

The first insulating layer A1 may have the first thickness T1, the conductive layer A2 may have the second thickness T2, the second insulating layer A3 may have the third thickness T3, and the third insulating layer A4 may have the fourth thickness T4. In this case, the second thickness T2 may be larger than each of the first thickness T1 and the fourth thickness T4 and smaller than the third thickness T3.

The first thickness T1 may be 10 Å to 100 Å. The second thickness T2 may be 100 Å to 600 Å. The third thickness T3 may be 600 Å to 900 Å. The fourth thickness T4 may be 20 Å to 200 Å.

By the relationship between the refractive indexes and/or the relationship between the thicknesses, a light L1 incident to a micro lens ML may be refracted and passed through multi-layer structure of the anti-reflection structure AL, and be well incident on the photoelectric converter PD. Accordingly, it is possible to provide the image sensor 503 having clear image quality by increasing the light reception rate.

In the image sensor 503 according to an implementation, the anti-reflection structure AL may include the conductive layer A2 made of titanium oxide (TiO2), which may entirely reduce the reflectivity of all colors of light, and may further reduce the reflectivity of blue light in particular. With this, the quantum efficiency (QE) of the blue pixels may be increased.

The first insulating layer A1 may also serve as a negative fixed charge layer. With this, the dark current and the white spot may be improved.

In addition, a predetermined negative potential (voltage) may be applied to the conductive layer A2 so that holes h+ are accumulated near the back side 1b of the first substrate 1. Accordingly, the effect of improving the dark current and the white spot may be further increased.

The first optical black pattern 52p is disposed on the anti-reflection structure AL. The first optical black pattern 52p may have a single layer structure or a multilayer structure of at least one of a titanium layer, a titanium nitride layer, and a tungsten layer.

Light blocking grid patterns 48a may be disposed on the anti-reflection structure AL in the pixel array region APS. Low refractive index grid patterns 50a may be respectively disposed on the light blocking grid patterns 48a. The light blocking grid pattern 48a and the low refractive index grid pattern 50a overlap the first pixel separator DTI1 and may have a planar grid shape. The light blocking grid pattern 48a may include, for example, at least one of titanium and titanium nitride. All of the low refractive index grid patterns 50a may have the same thickness and include the same organic material. The low refractive index grid pattern 50a may have a lower refractive index than color filters CF1 and CF2. For example, the low refractive index grid pattern 50a may have a refractive index of about less than or equal to 1.3. The light blocking grid pattern 48a and the low refractive index grid pattern 50a may prevent crosstalk between adjacent unit pixels UP.

A passivation layer 56 may be conformally disposed on the first optical black pattern 52p, the light blocking grid pattern 48a, and the low refractive index grid pattern 50a.

In the pixel array region APS, the color filters CF1 and CF2 may be disposed between the low refractive index grid patterns 50a and on the passivation layer 56.

The color filters CF1 and CF2 may respectively have one color among blue, green, and red. As another example, the color filters CF1 and CF2 may include other colors such as cyan, magenta, or yellow. In the image sensor according to the present implementation, the color filters CF1 and CF2 may be arranged in a bayer pattern. In another example, the color filters CF1 and CF2 may be arranged in a 2×2 tetra pattern, a 3×3 nona pattern, or a 4×4 hexadeca pattern.

Micro lenses ML may be disposed on the color filters CF1 and CF2 in the pixel array region APS. Edges of the micro lenses ML may be connected by contacting each other. The micro lenses ML may configure an array. The micro lenses ML may also be referred to as a “micro lens array.”

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the implementations of the present disclosure have been described with reference to the accompanying drawings, those skilled in the art will appreciate that may variations and modifications can be made to the implementations without departing from the spirit and scope of the claims and their equivalents. Therefore, the implementations described above are to be regarded as illustrative in all respects and not restrictive.

What is claimed is:

1. A semiconductor device including a plurality of unit pixels, wherein
each unit pixel of the plurality of unit pixels comprises:
a pair of transfer gates including a first transfer gate and a second transfer gate;
a photoelectric converter; and
a floating diffusion region spaced apart from the photoelectric converter,
wherein the first transfer gate and the second transfer gate are disposed asymmetrically with respect to the photoelectric converter and the floating diffusion region.

2. The semiconductor device of claim 1, wherein
the first transfer gate is disposed opposite to the second transfer gate with respect to an electron transfer pass center cross-section connecting the photoelectric converter and the floating diffusion region.

3. The semiconductor device of claim 1, wherein
the first transfer gate is closer to the photoelectric converter than the floating diffusion region, and the second transfer gate is closer to the floating diffusion region than the first transfer gate.

4. The semiconductor device of claim 3, wherein
the second transfer gate is closer to the floating diffusion region than the photoelectric converter.

5. The semiconductor device of claim 1, wherein
each unit pixel of the plurality of unit pixels is a rectangular shape in a plan view, and
the floating diffusion region is at one of four corners of each unit pixel of the plurality of unit pixels.

6. The semiconductor device of claim 5, wherein
the first transfer gate overlaps the photoelectric converter at least partially in a plan view and is spaced apart from the floating diffusion region, and
the second transfer gate overlaps the photoelectric converter at least partially in a plan view and contacts the floating diffusion region.

7. The semiconductor device of claim 6, wherein
the first transfer gate contacts the photoelectric converter above and below the first transfer gate, and
the second transfer gate contacts the floating diffusion region on a left side and a right side of the second transfer gate.

8. The semiconductor device of claim 7, wherein
the second transfer gate contacts the photoelectric converter above and below the second transfer gate.

9. The semiconductor device of claim 7, wherein:
a projected area of the first transfer gate and a projected area of the second transfer gate overlap at least partially on an electron transfer pass center cross-section.

10. The semiconductor device of claim 1, wherein:
the first transfer gate overlaps the photoelectric converter at least partially in a plan view and is spaced apart from the floating diffusion region, and
the second transfer gate overlaps the photoelectric converter at least partially in a plan view and contacts the floating diffusion region.

11. The semiconductor device of claim 10, wherein:
the first transfer gate contacts the photoelectric converter above and below the first transfer gate, and
the second transfer gate contacts the floating diffusion region on a left side and a right side of the second transfer gate.

12. The semiconductor device of claim 11, wherein
the second transfer gate contacts the photoelectric converter above and below the second transfer gate.

13. The semiconductor device of claim 11, wherein
a projected area of the first transfer gate and a projected area of the second transfer gate overlap at least partially on an electron transfer pass center cross-section.

14. The semiconductor device of claim 1, wherein
at least part of the plurality of unit pixels further include a source follower gate and a selection gate.

15. The semiconductor device of claim 14, wherein
at least part of the plurality of unit pixels further include a reset gate.

16. The semiconductor device of claim 15, wherein
a unit pixel including the source follower gate and the selection gate is different from a unit pixel including the reset gate.

17. A semiconductor device, comprising:
a first substrate having a first surface and a second surface opposite to the first surface, and including a pixel array region and an edge region, wherein the pixel array region includes a plurality of unit pixels;
an anti-reflection structure disposed on the second surface;
a pixel separator disposed on the first substrate to separate the plurality of unit pixels;
a color filter disposed on the anti-reflection structure;
a micro lens array disposed on the color filter;
a first interlayer insulating layer disposed on the first surface of the first substrate;
a first wiring layer disposed within the first interlayer insulating layer;
a second interlayer insulating layer disposed under the first interlayer insulating layer;
a second wiring layer disposed within the second interlayer insulating layer; and
a second substrate disposed under the second interlayer insulating layer,
wherein each unit pixel of the plurality of unit pixels comprises:
a pair of transfer gates including a first transfer gate and a second transfer gate;
a photoelectric converter; and
a floating diffusion region spaced apart from the photoelectric converter,
wherein the first transfer gate and the second transfer gate are disposed asymmetrically with respect to the photoelectric converter and the floating diffusion region.

18. The semiconductor device of claim 17, wherein
the first transfer gate is closer to the photoelectric converter than the floating diffusion region, and the second transfer gate is closer to the floating diffusion region than the first transfer gate.

19. A semiconductor device, comprising:
a first sub-chip, the first sub-chip comprising
a first substrate having a first surface and a second surface opposite to the first surface, wherein the first substrate includes a plurality of unit pixel array regions and an edge region,
an anti-reflection structure disposed on the second surface,
a pixel separator disposed on the first substrate to separate a plurality of unit pixels,
a color filter disposed on the anti-reflection structure,
a micro lens array disposed on the color filter,
a first interlayer insulating layer disposed on the first surface of the first substrate, and
a first wiring layer disposed within the first interlayer insulating layer;
a second sub-chip, the second sub-chip comprising
a second substrate disposed under the first interlayer insulating layer,
a second interlayer insulating layer disposed under the second substrate, and
a second wiring layer disposed within the second interlayer insulating layer; and
a third sub-chip, the third sub-chip comprising
a third interlayer insulating layer disposed under the second interlayer insulating layer,
a third wiring layer disposed within the third interlayer insulating layer, and
a third substrate disposed under the third interlayer insulating layer,
wherein each unit pixel of the plurality of unit pixels comprises a pair of transfer gates including a first transfer gate and a second transfer gate;
a photoelectric converter, and
a floating diffusion region spaced apart from the photoelectric converter,
wherein the first transfer gate and the second transfer gate are disposed asymmetrically with respect to the photoelectric converter and the floating diffusion region.

20. The semiconductor device of claim 19, wherein
the first transfer gate is closer to the photoelectric converter than the floating diffusion region, and the second transfer gate is closer to the floating diffusion region than the first transfer gate.
